(19) United States
(12) Patent Application Publication
(10) Pub. No.: US 2025/0185365 A1
(43) Pub. Date: Jun. 5, 2025

(54) THIN FILM TRANSISTOR BACK PANEL AND LIGHT-EMITTING DIODE DISPLAY PANEL AND MANUFACTURING METHOD THEREFOR

(71) Applicants: Huizhou China Star Optoelectronics Display Co., Ltd., Huizhou (CN); Shenzhen China Star Optoelectronics Semiconductor Display Technology Co., Ltd., Shenzhen (CN)

(72) Inventor: Chuanbao LUO, Huizhou (CN)

(73) Assignees: Huizhou China Star Optoelectronics Display Co., Ltd., Huizhou (CN); Shenzhen China Star Optoelectronics Semiconductor Display Technology Co., Ltd., Shenzhen (CN)

(21) Appl. No.: 17/598,896

(22) PCT Filed: Jul. 26, 2021
(86) PCT No.: PCT/CN2021/108315

§ 371 Date: Feb. 20, 2025

(30) Foreign Application Priority Data
Jul. 14, 2021 (CN) 202110794394.2

(51) Int. Cl. H10D 86/40; H01L 25/16; H10D 86/60; H10H 29/01

(52) U.S. Cl. CPC H10D 86/443; H01L 25/167; H10D 86/60; H10H 29/012

(57) ABSTRACT

Embodiments of the present disclosure provide a thin film transistor (TFT) back panel a light-emitting diode (LED) display panel and a manufacturing method therefor. In the TFT back panel provided in the embodiments of the present disclosure, a pressure-sensitive transistor is disposed. When a first pressure-sensitive material layer is subjected to a pressure, a pressure-sensitive transistor is turned on to generate a current, and a pressure signal is converted into an electrical signal. Changes in a pressure applied to the TFT back panel during transfer and pressing of an LED can be monitored in real time by monitoring a magnitude of the electrical signal.

### FIELD OF INVENTION

The present disclosure relates to the field of display technologies, and in particular, to a thin film transistor (TFT) back panel and a light-emitting diode (LED) display panel and a manufacturing method therefor.

### BACKGROUND OF INVENTION

A Mini/Micro LED (MLED) display technology has entered an accelerated development stage in recent years, and can be applied to application fields of small and medium-sized high value-added displays. Compared with an organic light-emitting diode (OLED) screen, the MLED display can show better performance in terms of costs, contrast, high brightness, and thin and light appearance. The MLED display technology relates to a TFT back panel technology and a back-end LED chip transfer technology. A back-end mass transfer technology is the bottleneck technology of Micro-LED mass production. The currently widely used transfer process is an anisotropic conductive adhesive (ACF) process.

### SUMMARY OF INVENTION

### Technical Problem

In the ACF transfer technology, it is necessary to squeeze the entire face of the ACF after bonding, so that Au balls in ACF glue are released, thereby realizing the connection between a TFT back panel and an LED chip. However, during the transfer process of the conventional LED devices, an excessive pressure applied to the TFT back panel often causes a short circuit in conduction of internal circuits, resulting in a low transfer yield.

### Technical Solution

Embodiments of the present disclosure provide a TFT back panel and an LED display panel and a manufacturing method therefor. When the TFT back panel is transferring LED devices and being squeezed, a pressure-sensitive transistor in the TFT back panel can monitor the pressure applied to the TFT back panel in real time, so as to avoid a short circuit in conduction of internal circuits caused by an excessive pressure applied to the TFT back panel.

An embodiment of the present disclosure provides a TFT back panel, including a display transistor area, an LED bonding area, and a pressure-sensitive transistor area.

A display transistor is disposed in the display transistor area, and the display transistor includes a first active layer, a first gate, a first source, and a first drain.

A first conductive layer is disposed on a top face of the LED bonding area, and the first conductive layer is electrically connected to the first drain.

A pressure-sensitive transistor is disposed in the pressure-sensitive transistor area, and the pressure-sensitive transistor includes a second active layer, a gate insulating layer, a second gate, a first pressure-sensitive material layer, and a second conductive layer that are stacked in sequence.

### Beneficial Effects

In the TFT back panel provided in the embodiments of the present disclosure, a pressure-sensitive transistor is disposed. When a first pressure-sensitive material layer is under pressure, a second conductive layer on one side of the first pressure-sensitive material layer forms a low potential, and a second gate located on an other side of the first pressure-sensitive material layer forms a high potential. The pressure-sensitive transistor is turned on to generate a current, and a pressure signal is converted into an electrical signal. Changes in a pressure applied to the TFT back panel during transfer and pressing of an LED can be monitored in real time by monitoring a magnitude of the electrical signal. Therefore, a short circuit in conduction of internal circuits caused by an excessive pressure applied to the TFT back panel can be avoided, and a transfer yield can be improved.

### BRIEF DESCRIPTION OF DRAWINGS

To describe the technical solutions in the embodiments of the present disclosure more clearly, the following briefly describes the accompanying drawings required for describing the embodiments. Obviously, the accompanying drawings in the following descriptions are merely some embodiments of the present disclosure, and a person of ordinary skill in the art can further obtain other accompanying drawings according to the accompanying drawings without creative efforts.

For a more complete understanding of the present disclosure and beneficial effects thereof, the present disclosure is described below with reference to the accompanying drawings. In the following descriptions, same parts are denoted by same reference numerals.

FIG. 1 is a schematic diagram of a first structure of a TFT back panel according to an embodiment of the present disclosure.

FIG. 2 is a schematic diagram of a second structure of the TFT back panel according to an embodiment of the present disclosure.

FIG. 3 is a schematic diagram of a first structure of an LED display panel according to an embodiment of the present disclosure.

FIG. 4 is a schematic diagram of a second structure of an LED display panel according to an embodiment of the present disclosure.

### DETAILED DESCRIPTION OF PREFERRED EMBODIMENTS

### Implementations of the Present Invention

The technical solutions of the embodiments of the present disclosure are clearly and completely described in the following with reference to the accompanying drawings of the embodiments of the present disclosure. Apparently, the described embodiments are merely some but not all of the embodiments of the present disclosure. All other embodiments obtained by a person skilled in the art based on the embodiments of the present disclosure without creative efforts shall fall within the protection scope of the present disclosure.

The embodiment of the present disclosure provides a TFT back panel configured to transfer an LED device. During the transfer, an anisotropic conductive adhesive (ACF) is first attached to the TFT back panel, then the LED device is disposed on the ACF, and finally a pressure is applied to the TFT back panel having the ACF attached thereto and the LED device disposed thereon, so as to release conductive balls (such as gold balls) in the ACF to realize the electrical connection between the LED device and the TFT back panel.

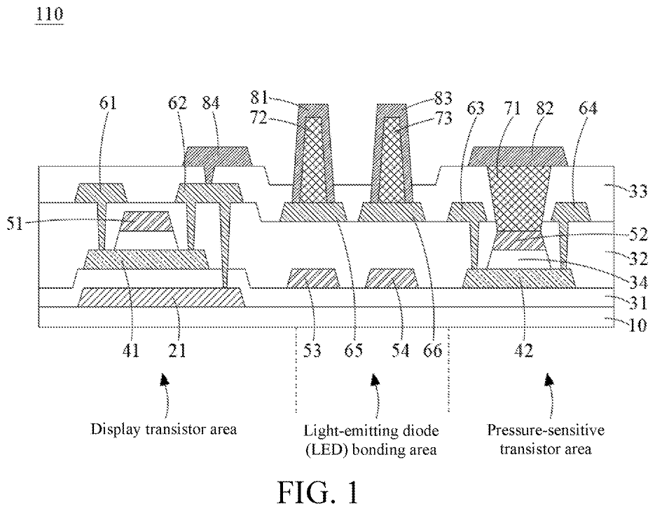

Referring to FIG. 1, FIG. 1 is a schematic diagram of a first structure of a TFT back panel according to an embodiment of the present disclosure. A TFT back panel 110 includes a display transistor area, an LED bonding area, and a pressure-sensitive transistor area.

A display transistor is disposed in the display transistor area, and the display transistor includes a first active layer 41, a first gate 51, a first source 61, and a first drain 62.

A first conductive layer 81 is disposed on a top face of the LED bonding area, and the first conductive layer 81 is electrically connected to the first drain 62.

A pressure-sensitive transistor is disposed in the pressure-sensitive transistor area. The pressure-sensitive transistor includes a second active layer 42, a gate insulating layer 34, a second gate 52, a first pressure-sensitive material layer 71, and a second conductive layer 82 that are stacked in sequence.

It can be understood that the second gate 52, the first pressure-sensitive material layer 71, and the second conductive layer 82 can constitute a pressure-sensitive capacitor. After the ACF is attached to the TFT back panel 110 and the LED device is disposed on the TFT back panel, when a pressure is applied to the TFT back panel 110 using a pressure application device, the material in the first pressure-sensitive material layer 71 is polarized due to the pressure, and a potential is formed at two ends of the capacitor, causing the second gate 52 to form a high potential and the second conductive layer 82 to form a low potential. The pressure-sensitive transistor is thus turned on to generate a current, and a pressure signal is converted into an electrical signal, thereby monitoring changes in the pressure applied to the TFT back panel 110 during the ACF pressing process in real time.

In the TFT back panel 110 provided in the embodiments of the present disclosure, a pressure-sensitive transistor is disposed. When a first pressure-sensitive material layer 71 is under pressure, a second conductive layer 82 on one side of the first pressure-sensitive material layer 71 forms a low potential, and a second gate 52 located on an other side of the first pressure-sensitive material layer 71 forms a high potential. The pressure-sensitive transistor is turned on to generate a current, and a pressure signal is converted into an electrical signal. Changes in the pressure applied to the TFT back panel 110 during transfer and pressing of an LED can be monitored in real time by monitoring a magnitude of the electrical signal. Therefore, a short circuit in conduction of internal circuits caused by an excessive pressure applied to the TFT back panel 110 can be avoided, and a transfer yield can be improved.

It can be understood that the display transistor area can be disposed corresponding to a pixel area (for example, a red pixel area, a green pixel area, and a blue pixel area), and the pressure-sensitive transistor area can be disposed corresponding to a non-pixel area (that is, a spacing area between the pixel areas).

Referring to FIG. 1, the pressure-sensitive transistor can further include a second source 63 and a second drain 64. The second source 63 and the second drain 64 are electrically connected to two ends of the second active layer 42 respectively.

For example, a material of the first pressure-sensitive material layer 71 is polyvinylidene fluoride (PVDF). Certainly, the material of the first pressure-sensitive material layer 71 can alternatively be other polyalkylidene fluoride materials.

In order to improve the pressure-sensitive characteristics of the first pressure-sensitive material layer 71, the material of the first pressure-sensitive material layer 71 can be doped with a metal element. The metal element includes at least one of titanium and zirconium, and a weight percentage of the metal element in the material of the first pressure-sensitive material layer 71 is in a range of 5 wt % to 10 wt %, for example, 5 wt %, 6 wt %, 7 wt %, 8 wt %, 9 wt %, 10 wt %, or the like.

For example, a thickness of the first pressure-sensitive material layer 71 can be in a range of 3 μm to 10 μm, for example, 3 μm, 4 μm, 5 μm, 6 μm, 7 μm, 8 μm, 9 μm, 10 μm, or the like.

In some embodiments, a top face of the display transistor area and a top face of the pressure-sensitive transistor area are both lower than the top face of the LED bonding area. That is, the top face of the LED bonding area protrudes from other areas on the TFT back panel 110. After an anisotropic conductive adhesive 130 (ACF) is attached to the TFT back panel 110 and the LED device 120 is disposed, when a pressure is applied to an entire face of the ACF, due to a higher position of the LED device 120, the ACF under the LED device 120 is more susceptible to force, and conductive balls in the ACF are released, so that the LED device 120 is electrically connected to the first conductive layer 81. It can be understood that when a position of the top face of the LED bonding area is relatively low, the ACF corresponding to the position of the LED device 120 is not easily stressed, resulting in the insufficient release of the conductive balls in the ACF, which in turn makes a poor effect of the electrical connection between the LED device 120 and the TFT back panel 110. That is, a poor transfer occurs.

In some embodiments, the top face of the pressure-sensitive transistor area is higher than the top face of the display transistor area, or is flush with the top face of the display transistor area. It can be understood that the pressure-sensitive transistor is configured to monitor the pressure applied to the TFT back panel 110. If the top face of the pressure-sensitive transistor area is lower than the top face of the display transistor area, even at a lowest position in the three areas (the display transistor area, the LED bonding area, and the pressure-sensitive transistor area), when the pressure application device applies a pressure to the TFT back panel 110, a contact effect between the pressure-sensitive transistor and the pressure application device is inevitably poor. Therefore, it is difficult for the pressure-sensitive transistor to sense the pressure, or the sensed pressure is inaccurate.

With reference to FIG. 1, a third conductive layer 83 can further be disposed on the top face of the LED bonding area, and the first conductive layer 81 is spaced apart from the third conductive layer 83. It is known that the first conductive layer 81 is electrically connected to the first drain of the display transistor. The first conductive layer 81 and the third conductive layer 83 can respectively constitute an anode and a cathode of the LED device 120, or the first conductive layer 81 and the third conductive layer 83 can respectively constitute a cathode and an anode of the LED device 120.

The material of each of the first conductive layer 81, the second conductive layer 82, and the third conductive layer 83 can be a transparent conductive metal oxide (for example, indium tin oxide) or metal. During preparation, an indium tin oxide (ITO) layer can be deposited on the entire face using a physical vapor deposition method, and then the ITO layer can be patterned to obtain the first conductive layer 81, the second conductive layer 82, and the third conductive layer 83.

With reference to FIG. 1, a second pressure-sensitive material layer 72 can be disposed below the first conductive layer 81, and a third pressure-sensitive material layer 73 can be disposed below the third conductive layer 83. The first conductive layer 81 is heightened using the second pressure-sensitive material layer 72, and the third conductive layer 83 is heightened using the third pressure-sensitive material layer 73. During transfer of an LED, when a pressure is applied to the TFT back panel 110, the second pressure-sensitive material layer 72 and the third pressure-sensitive material layer 73 can also play a buffering role, so as to reduce or eliminate the phenomenon of crushing lines in the TFT back panel 110 during transfer of the LED.

For example, a material of the second pressure-sensitive material layer 72 is PVDF. Certainly, the material of the second pressure-sensitive material layer 72 can alternatively be other polyalkylidene fluoride materials. In order to improve the pressure-sensitive characteristics of the second pressure-sensitive material layer 72, the material of the second pressure-sensitive material layer 72 can be doped with a metal element. The metal element includes at least one of titanium and zirconium, and a weight percentage of the metal element in the material of the second pressure-sensitive material layer 72 is in a range of 5 wt % to 10 wt %, for example, 5 wt %, 6 wt %, 7 wt %, 8 wt %, 9 wt %, 10 wt %, or the like. For example, a thickness of the second pressure-sensitive material layer 72 can be in a range of 3 μm to 10 μm, for example, 3 μm, 4 μm, 5 μm, 6 μm, 7 μm, 8 μm, 9 μm, 10 μm, or the like.

For example, a material of the third pressure-sensitive material layer 73 is PVDF. Certainly, the material of the third pressure-sensitive material layer 73 can alternatively be other polyalkylidene fluoride materials. In order to improve the pressure-sensitive characteristics of the third pressure-sensitive material layer 73, the material of the third pressure-sensitive material layer 73 can be doped with a metal element. The metal element includes at least one of titanium and zirconium, and a weight percentage of the metal element in the material of the third pressure-sensitive material layer 73 is in a range of 5 wt % to 10 wt %, for example, 5 wt %, 6 wt %, 7 wt %, 8 wt %, 9 wt %, 10 wt %, or the like. For example, a thickness of the third pressure-sensitive material layer 73 can be in a range of 3 μm to 10 μm, for example, 3 μm, 4 μm, 5 μm, 6 μm, 7 μm, 8 μm, 9 μm, 10 μm, or the like.

In some embodiments, the first conductive layer 81, the second conductive layer 82, and the third conductive layer 83 are located in a same layer in the TFT back panel 110 and can be formed in the same manufacturing process.

The first pressure-sensitive material layer 71, the second pressure-sensitive material layer 72, and the third pressure-sensitive material layer 73 are located in a same layer in the TFT back panel 110 and can be formed in the same manufacturing process. For example, the material of the second pressure-sensitive material layer 72, the material of the third pressure-sensitive material layer 73, and the material of the first pressure-sensitive material layer 71 are the same.

With reference to FIG. 1, a light-shielding layer 21 is further disposed in the display transistor area. The light-shielding layer 21 is disposed corresponding to the first active layer 41, so as to prevent electrical properties of the first active layer 41 from being affected as a result of irradiating the first active layer with rays of light.

For example, the first drain 62 is connected to the light-shielding layer 21 to improve current characteristics of the display transistor.

For example, the material of the first active layer 41 and the material of the second active layer 42 can both be metal oxide semiconductor materials, such as indium gallium zinc oxide (IGZO). A conductive area can be disposed at each of two ends of the first active layer 41, and the conductive areas at two ends are electrically connected to the first source 61 and the first drain 62 respectively. A conductive area can be disposed at each of two ends of the second active layer 42, and the conductive areas at two ends are electrically connected to the second source 63 and the second drain 64 respectively. The conductive area can be an N-type doped area.

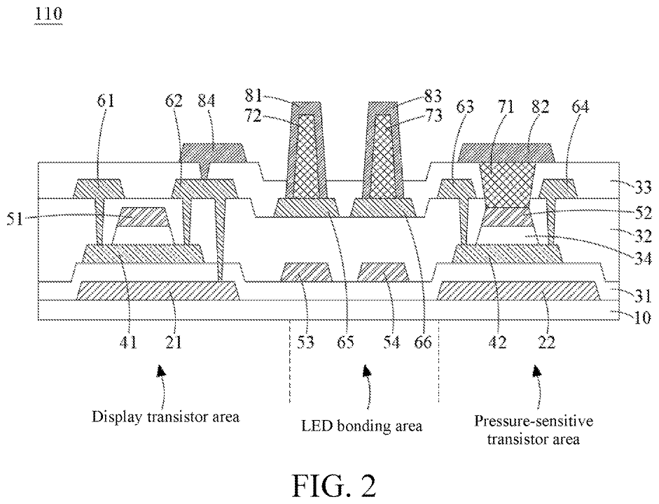

Referring to FIG. 2, FIG. 2 is a schematic diagram of a second structure of the TFT back panel according to an embodiment of the present disclosure. The pressure-sensitive transistor can further include a third gate 22 and a first insulating layer 31. The first insulating layer 31 is disposed on a side of the second active layer 42 that faces away from the gate insulating layer 34, and the third gate 22 is disposed on a side of the first insulating layer 31 that faces away from the second active layer 42. It can be seen that, in the present embodiment, the pressure-sensitive transistor is a double-gate thin film transistor, and the second gate 52 (a top gate) and the third gate 22 (a bottom gate) are respectively disposed on two sides of the second active layer 42. By using dual gates to jointly control the pressure-sensitive transistor to be turned on, the current in the pressure-sensitive transistor is larger, the signal is stronger, and a response to the changes in the pressure applied to the TFT back panel 110 is more sensitive.

With reference to FIG. 2, the third gate 22 and the light-shielding layer 21 can be located in the same layer in the TFT back panel 110 and can be formed in the same manufacturing process.

With reference to FIG. 2, in some embodiments, the TFT back panel 110 can include a substrate 10, a first metal layer, a first insulating layer 31, a semiconductor layer, a gate insulating layer 34, a second metal layer, a second insulating layer 32, a third metal layer, a third insulating layer 33, a pressure-sensitive layer, and a conductive film layer.

The first metal layer includes a light-shielding layer 21 and a third gate 22. The main difference between the TFT back panel 110 of FIG. 1 and the TFT back panel 110 of FIG. 2 lies in that the first metal layer in the TFT back panel 110 in FIG. 1 does not include the third gate 22, and the first metal layer in the TFT back panel 110 in FIG. 2 includes the third gate 22.

The semiconductor layer includes a first active layer 41 and a second active layer 42.

The second metal layer includes a first gate 51, a second gate 52, a first conductive pattern 53, and a second conductive pattern 54. The first conductive pattern 53 and the second conductive pattern 54 are both disposed in the LED bonding area. The first conductive pattern 53 is disposed corresponding to the first conductive layer 81, and the second conductive pattern 54 is disposed corresponding to the third conductive layer 83.

The third metal layer includes a first source 61, a first drain 62, a second source 63, a second drain 64, a third conductive pattern 65, and a fourth conductive pattern 66. The third conductive pattern 65 and the fourth conductive pattern 66 are both disposed in the LED bonding area. The third conductive pattern 65 is disposed corresponding to the first conductive layer 81 and is connected to the first conductive layer 81. The fourth conductive pattern 66 is disposed corresponding to the third conductive layer 83 and is connected to the third conductive layer 83. This is equivalent to increasing thicknesses of the first conductive layer 81 and the third conductive layer 83 respectively, thereby reducing the resistance. The first conductive pattern 53 can further be connected to the third conductive pattern 65, and the second conductive pattern 54 can further be connected to the fourth conductive pattern 66. This is equivalent to further increasing the thicknesses of the first conductive layer 81 and the third conductive layer 83 respectively, thereby further reducing the resistance. In addition, the first conductive pattern 53, the second conductive pattern 54, the third conductive pattern 65, and the fourth conductive pattern 66 can further play a role of heightening the LED bonding area.

For example, the substrate 10 can be a glass base plate. The material of the first metal layer, the material of the second metal layer, and the material of the third metal layer can each include at least one of molybdenum, aluminum, copper, titanium, tungsten, and alloys of the above metal. The first insulating layer 31, the second insulating layer 32, and the third insulating layer 33 can each be a silicon nitride (SiNx) layer, a silicon oxide (SiOx) layer, or a laminated composite layer of a silicon nitride layer and a silicon oxide layer.

The pressure-sensitive layer includes a first pressure-sensitive material layer 71, a second pressure-sensitive material layer 72, and a third pressure-sensitive material layer 73. A through hole can be provided on the third insulating layer 33, so that the first pressure-sensitive material layer 71 is disposed in the through hole.

The conductive film layer includes a first conductive layer 81, a second conductive layer 82, a third conductive layer 83, and a fourth conductive layer 84. The fourth conductive layer 84 is connected to the first drain 62 via a through hole on the third insulating layer 33, and the fourth conductive layer 84 is connected to the first conductive layer 81.

The first source 61 is connected to one end of the first active layer 41 via a through hole on the second insulating layer 32, and the first drain 62 is connected to an other end of the first active layer 41 via a through hole on the second insulating layer 32. The second source 63 is connected to one end of the second active layer 42 via the through hole on the second insulating layer 32, and the second drain 64 is connected to an other end of the second active layer 42 via the through hole on the second insulating layer 32. The first drain 62 is connected to the light-shielding layer 21 via through holes located on the first insulating layer 31 and the second insulating layer 32.

With reference to FIG. 1 and FIG. 2, it can be seen that the pressure-sensitive transistor in FIG. 1 is a top-gate thin film transistor (the second gate 52 is a top gate), and the pressure-sensitive transistor in FIG. 2 is a double-gate thin film transistor (the second gate 52 is the top gate, and the third gate 22 is a bottom gate). The display transistor in FIG. 1 and the display transistor in FIG. 2 are both top-gate (TG) thin film transistors (the first gate 51 is a top gate). It can be understood that the display transistors can further be other types of thin film transistors, such as a back channel etch (BCE) type thin film transistor, an etch stop type (ESL) thin film transistor, and a dual-gate thin film transistor.

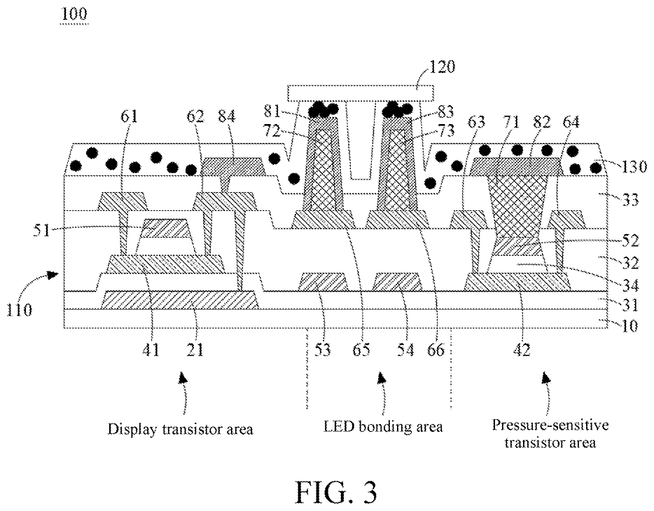

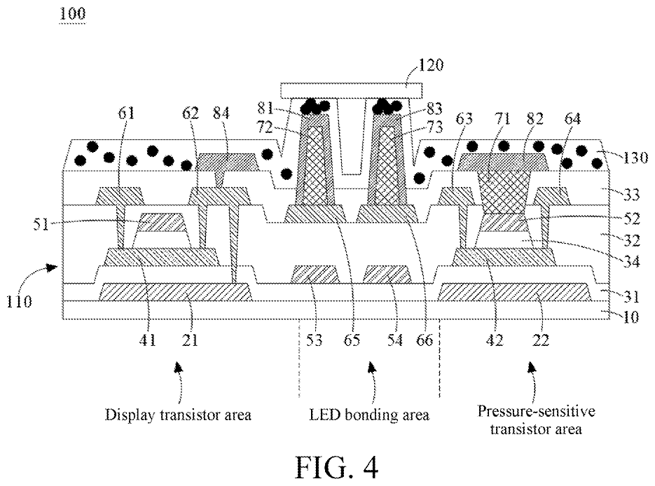

An embodiment of the present disclosure further provides an LED display panel. Referring to FIG. 3 and FIG. 4, FIG. 3 is a schematic diagram of a first structure of an LED display panel according to an embodiment of the present disclosure, and FIG. 4 is a schematic diagram of a second structure of an LED display panel according to an embodiment of the present disclosure. The LED display panel 100 can include a TFT back panel 110 and an LED device 120, and the TFT back panel 110 can be the TFT back panel 110 described in any of the above embodiments. The LED device 120 is electrically connected to the first conductive layer 81.

With reference to FIG. 3 and FIG. 4, the LED device 120 can further be electrically connected to the third conductive layer 83.

With reference to FIG. 1, FIG. 2, FIG. 3, and FIG. 4, it can be seen that the LED display panel 100 shown in FIG. 3 includes the TFT back panel 110 shown in FIG. 1, and the LED display panel 100 shown in FIG. 4 includes the TFT back panel 110 shown in FIG. 2. The TFT back panel 110 shown in FIG. 1 and the TFT back panel 110 shown in FIG. 2 have been described above, and the details will not be described herein again.

With reference to FIG. 3 and FIG. 4, an anisotropic conductive glue 130 is provided between the LED device 120 and the first conductive layer 81 and the third conductive layer 83, and the LED device 120 is electrically connected to the first conductive layer 81 and the third conductive layer 83 using the anisotropic conductive glue 130.

For example, the LED device 120 can be a mini LED or a micro LED.

With reference to FIG. 3 and FIG. 4, an embodiment of the present disclosure further provides a method for manufacturing an LED display panel. The method includes:
providing a TFT back panel 110, wherein the TFT back panel 110 can be the TFT back panel 110 described in any of the above embodiments;
providing an anisotropic conductive adhesive 130, and attaching the anisotropic conductive adhesive 130 to a side of the TFT back panel 110 having the first conductive layer 81 disposed thereon;
providing an LED device 120, and attaching, corresponding to the first conductive layer 81, the LED device 120 to the anisotropic conductive adhesive 130; and
providing a pressure application device, and applying, using the pressure application device, a pressure to a side of the TFT back panel 110 having the LED device 120 and the anisotropic conductive adhesive 130 disposed thereon, so that the LED device 120 is electrically connected to the first conductive layer 81.

The pressure application device includes a pressure application module and a control module. The pressure application module is configured to apply a pressure to the TFT back panel 110. The control module is connected to the pressure application module to control a magnitude of the pressure applied by the pressure application module. The control module is further connected to the pressure-sensitive transistor in the TFT back panel 110, so as to receive a pressure magnitude fed back by the pressure-sensitive transistor, and adjusts, according to the pressure magnitude fed back by the pressure-sensitive transistor, the pressure applied by the pressure application module to the TFT back panel 110.

It can be understood that, because a pressure-sensitive transistor is disposed in the TFT back panel 110, and the pressure-sensitive transistor can sense a magnitude of the pressure applied to the TFT back panel 110, after the pressure-sensitive transistor feeds back the magnitude of the sensed pressure to the control module of the pressure application device, the control module can determine whether the pressure applied to the TFT back panel 110 at this point is within the bearable range of the TFT back panel. If the pressure is greater than a pressure limit of the TFT back panel 110, the control module can control the pressure application module to reduce the pressure applied to the TFT back panel 110, so as to prevent the TFT back panel 110 from being over-stressed and causing short circuits due to conduction of the internal circuit. If it is found that the pressure applied to the TFT back panel 110 at this point is too small to electrically connect the LED device 120 to the first conductive layer 81 or to achieve a desirable conduction effect, the control module can also control the pressure application module to increase the pressure applied to the TFT back panel 110.

The TFT back panel and the LED display panel and the method for manufacturing same provided in the embodiments of the present disclosure are described in detail above. The principles and implementations of the present disclosure are described by using specific examples in this specification, and the descriptions of the foregoing embodiments are merely used for helping understand the present disclosure. Meanwhile, a person of ordinary skill in the art can make modifications to the specific implementations and application range according to the ideas of the present disclosure. In conclusion, the content of the specification is not to be construed as a limitation to the present disclosure.

1. A thin film transistor (TFT) back panel, comprising a display transistor area, a light-emitting diode (LED) bonding area, and a pressure-sensitive transistor area, wherein
a display transistor is disposed in the display transistor area, and the display transistor comprises a first active layer, a first gate, a first source, and a first drain;
a first conductive layer is disposed on a top face of the LED bonding area, and the first conductive layer is electrically connected to the first drain; and
a pressure-sensitive transistor is disposed in the pressure-sensitive transistor area, and the pressure-sensitive transistor comprises a second active layer, a gate insulating layer, a second gate, a first pressure-sensitive material layer, and a second conductive layer that are stacked in sequence.

2. The TFT back panel as claimed in claim 1, wherein a material of the first pressure-sensitive material layer comprises polyvinylidene fluoride.

3. The TFT back panel as claimed in claim 2, wherein the material of the first pressure-sensitive material layer is doped with a metal element, and the metal element comprises at least one of titanium and zirconium.

4. The TFT back panel as claimed in claim 3, wherein a weight percentage of the metal element in the material of the first pressure-sensitive material layer is in a range of 5 wt % to 10 wt %.

5. The TFT back panel as claimed in claim 1, wherein a top face of the display transistor area and a top face of the pressure-sensitive transistor area are both lower than the top face of the LED bonding area.

6. The TFT back panel as claimed in claim 1, wherein a top face of the pressure-sensitive transistor area is higher than a top face of the display transistor area.

7. The TFT back panel as claimed in claim 1, wherein a top face of the pressure-sensitive transistor area is flush with a top face of the display transistor area.

8. The TFT back panel as claimed in claim 1, wherein a third conductive layer is further disposed on the top face of the LED bonding area, and the first conductive layer and the third conductive layer are in a spaced arrangement.

9. The TFT back panel as claimed in claim 8, wherein a second pressure-sensitive material layer is disposed under the first conductive layer, a third pressure-sensitive material layer is disposed under the third conductive layer, and a material of the second pressure-sensitive material layer, a material of the third pressure-sensitive material layer, and a material of the first pressure-sensitive material layer are the same.

10. The TFT back panel as claimed in claim 1, wherein the pressure-sensitive transistor further comprises a third gate and a first insulating layer, the first insulating layer is disposed on a side of the second active layer that faces away from the gate insulating layer, and the third gate is disposed on a side of the first insulating layer that faces away from the second active layer.

11. An LED display panel, comprising a TFT back panel and an LED device, wherein the TFT back panel is the TFT back panel as claimed in claim 1; and the LED device is electrically connected to the first conductive layer.

12. The LED display panel as claimed in claim 11, wherein a material of the first pressure-sensitive material layer comprises polyvinylidene fluoride.

13. The LED display panel as claimed in claim 12, wherein the material of the first pressure-sensitive material layer is doped with a metal element, the metal element comprises at least one of titanium and zirconium, and a weight percentage of the metal element in the material of the first pressure-sensitive material layer is in a range of 5 wt % to 10 wt %.

14. The LED display panel as claimed in claim 11, wherein a top face of the display transistor area and a top face of the pressure-sensitive transistor area are both lower than a top face of the LED bonding area.

15. The LED display panel as claimed in claim 11, wherein a top face of the pressure-sensitive transistor area is higher than a top face of the display transistor area.

16. The LED display panel as claimed in claim 11, wherein a top face of the pressure-sensitive transistor area is flush with a top face of the display transistor area.

17. The LED display panel as claimed in claim 11, wherein a third conductive layer is further disposed on a top face of the LED bonding area, and the first conductive layer and the third conductive layer are in a spaced arrangement.

18. The LED display panel as claimed in claim 17, wherein a second pressure-sensitive material layer is disposed under the first conductive layer, a third pressure-sensitive material layer is disposed under the third conductive layer, and a material of the second pressure-sensitive material layer, a material of the third pressure-sensitive material layer, and a material of the first pressure-sensitive material layer are the same.

19. The LED display panel as claimed in claim 11, wherein the pressure-sensitive transistor further comprises a third gate and a first insulating layer, the first insulating layer is disposed on a side of the second active layer that faces away from the gate insulating layer, and the third gate is disposed on a side of the first insulating layer that faces away from the second active layer.

20. A method for manufacturing an LED display panel, the method comprising:
providing a TFT back panel, wherein the TFT back panel is the TFT back panel as claimed in claim 1;
providing an anisotropic conductive adhesive, and attaching the anisotropic conductive adhesive to a side of the TFT back panel having the first conductive layer disposed thereon;
providing an LED device, and attaching, corresponding to the first conductive layer, the LED device to the anisotropic conductive adhesive; and
providing a pressure application device, and applying, using the pressure application device, a pressure to a side of the TFT back panel having the LED device and the anisotropic conductive adhesive disposed thereon, so that the LED device is electrically connected to the first conductive layer, wherein
the pressure application device comprises a pressure application module and a control module, the pressure application module is configured to apply a pressure to the TFT back panel, the control module is connected to the pressure application module to control a magnitude of the pressure applied by the pressure application module, and the control module is further connected to the pressure-sensitive transistor in the TFT back panel, so as to receive a pressure magnitude fed back by the pressure-sensitive transistor, and adjust, according to the pressure magnitude fed back by the pressure-sensitive transistor, the pressure applied by the pressure application module to the TFT back panel.
